(19) United States
(12) Patent Application Publication
(10) Pub. No.: US 2026/0150478 A1
(43) Pub. Date: May 28, 2026

(54) PEROVSKITE SOLAR CELL AND METHOD FOR PREPARING THE SAME

(71) Applicant: GUANGDONG BILIGHT INTELLIGENT MANUFACTURING TECHNOLOGY CO., LTD., Dongguan (CN)

(72) Inventors: Kuan-Jung CHEN, Dongguan (CN); Wei-Chia FANG, Dongguan (CN); Chung-Chin HSIAO, Dongguan (CN); Tzu-Chien WEI, Dongguan (CN)

(21) Appl. No.: 19/368,031

(22) Filed: Oct. 24, 2025

(30) Foreign Application Priority Data
Nov. 22, 2024 (CN) 202411688396.3

(51) Int. Cl. H10K 30/85; H10K 30/50; H10K 71/40; H10K 85/50; H10K 85/60

(52) U.S. Cl. CPC H10K 30/85; H10K 30/50; H10K 71/441; H10K 85/50; H10K 85/60

(57) ABSTRACT

The present application relates to the field of solar cell technology, and in particular to a perovskite solar cell and a method for preparing the same. The perovskite solar cell includes: a first electrode, a second electrode, and a perovskite layer arranged between the first electrode and the second electrode. An electron transport layer is arranged between the perovskite layer and the first electrode A material of the electron transport layer includes a metal oxide, and an organic molecule represented by Formula I is arranged between the perovskite layer and the electron transport layer. X in the organic molecule is adjacent to the electron transport layer, and the —NH₃⁺ in the organic molecule is adjacent to the perovskite layer.

### CROSS-REFERENCE TO RELATED APPLICATION

Pursuant to 35 U.S.C. § 119 and the Paris Convention, this application claims the benefit of Chinese Patent Application No. 202411688396.3 filed Nov. 22, 2024, the contents of which are incorporated herein by reference.

### BACKGROUND

### Technical Field

The present application relates to the technical field of solar cells, and in particular to a perovskite solar cell and a method for preparing the same.

### Description of Related Art

Perovskite materials are a class of semiconductor materials with uniform size and high color purity. Their elemental composition has a crystal structure similar to the mineral CaTiO₃. Perovskite materials features strong light absorption capability and a wide absorption range, offering significant advantages in the optoelectronics field. For example, perovskite solar cells (PSCs), which use perovskite materials as the light-absorbing layer, have seen rapid development. Their exceptional carrier mobility, high absorption coefficient, and low-cost solution processing have attracted widespread attention from the business community.

Metal oxides are generally used as electron transport layer materials in perovskite solar cells. The surface of such electron transport layers generally produces a porous structure, and the crystal structure of the perovskite film still has crystal defects. Many pores present between the perovskite layer and the electron transport layer of the metal oxide, which leads to a decrease in the performance of the perovskite solar cell.

### SUMMARY

It is one of objectives of embodiments of the present application to provide a perovskite solar cell and a method for preparing the same, aiming to address the technical problem of improving the interlayer gap between the electron transport layer and the perovskite layer in a perovskite solar cell to enhance the performance thereof.

To achieve the above objective, the following technical solutions are adopted by the present application:

In a first aspect, embodiments of the present application provides a perovskite solar cell comprising: a first electrode, a second electrode, a perovskite layer, which is arranged between the first electrode and the second electrode; and an electron transport layer, which is arranged between the perovskite layer and the first electrode. A material of the electron transport layer comprises a metal oxide. An organic molecule represented by Formula I is arranged between the perovskite layer and the electron transport layer;

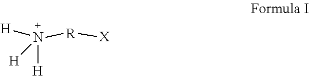

in which, X comprises at least one of a carbonyl group, a carboxyl group, a hydroxyl group, a thiol group, an imine group, a cyano group, and a nitro group, R is —(CH₂)ₙ— or —(CH₂)ₙ— substituted with a hydroxyl group, and n is an integer greater than or equal to 1; and X in the organic molecule is adjacent to the electron transport layer, and —NH₃⁺ in the organic molecule is adjacent to the perovskite layer.

In some embodiments, X is a carboxyl group; and/or n=2 to 5.

In some embodiments, a molar ratio of the organic molecule to the perovskite material in the perovskite layer is (0.01 to 0.04):1.

In some embodiments, the metal oxide comprises at least one of TiO₂, NiOₓ, SnO₂, ZrO₂, and ZnO; and/or,
a hole transport layer is arranged between the perovskite layer and the second electrode.

In a second aspect, embodiments of the present application provides a method for preparing a perovskite solar cell, the method comprising:
preparing an electron transport layer comprising a metal oxide on a first electrode;
depositing a perovskite precursor solution comprising an organic molecule represented by Formula I on a surface of the electron transport layer, followed by heat treatment to obtain a perovskite layer;
preparing a second electrode on the perovskite layer;

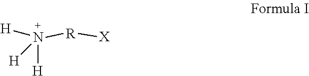

in which, X comprises at least one of a carbonyl group, a carboxyl group, a hydroxyl group, a thiol group, an imine group, a cyano group, and a nitro group, R is —(CH₂)ₙ— or —(CH₂)ₙ— substituted with a hydroxyl group, and n is an integer greater than or equal to 1.

In some embodiments, the perovskite precursor solution is prepared by the following steps:
dissolving a halide salt corresponding to the organic molecule represented by Formula I and a perovskite precursor in a solvent to obtain the perovskite precursor solution;
or alternatively, dissolving an organic molecule represented by Formula II and a perovskite precursor in the solvent, and adjusting a pH value of a resulting solution to protonate an amino terminus of the organic molecule represented by Formula II to obtain the perovskite precursor solution;

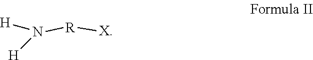

In some embodiments, a molar ratio of the halide salt corresponding to the organic molecule represented by Formula I to the perovskite precursor is (0.01-0.04):1; or a molar ratio of the organic molecule represented by Formula II to the perovskite precursor is (0.01-0.04):1.

In some embodiments, the solvent comprises at least one of dimethyl sulfoxide and N,N-dimethylformamide.

In some embodiments, a temperature of the heat treatment is 100° C. to 150° C.

In some embodiments, the step of preparing the second electrode on the perovskite layer comprises: preparing a hole transport layer on a surface of the perovskite layer, and preparing the second electrode on the hole transport layer.

Advantages of the perovskite solar cell provided in embodiments of the first aspect of the present application are summarized as follows:

The perovskite solar cell has a unique organic molecule arranged between the perovskite layer and the electron transport layer containing a metal oxide. The group X of the organic molecule can bind to the metal oxide on the surface of the electron transport layer, and the protonated amino group (—NH₃⁺) can bind to the perovskite material of the perovskite layer. Based on the action of the organic molecule, the pores between the electron transport layer and the perovskite layer can be improved, making the interlayer bonding tighter, which is conducive to improving the electron transport performance, thereby improving the energy conversion efficiency of the perovskite solar cell.

Advantages of the second aspect of embodiments of the present application are summarized as follows:

In the method for preparing the perovskite solar cell, the perovskite precursor solution comprising the organic molecule represented by Formula I is deposited on a surface of the electron transport layer, then heat treatment is performed to obtain the perovskite layer. In this process, the organic molecule represented by Formula I acts as a molecular template, and the group X can combine with the metal oxide, while the protonated amino group (—NH₃⁺) can combine with the perovskite material, which is conducive to the nucleation of perovskite crystallization, allowing the perovskite to crystallize and grow along the porous surface of the electron transport layer and fill the porous structure of the electron transport layer. The generated perovskite layer can be more tightly combined with the electron transport layer, which is beneficial to improving the electron transport performance. The perovskite solar cell finally prepared has good energy conversion efficiency.

### BRIEF DESCRIPTION OF THE DRAWINGS

In order to more clearly illustrate the technical solutions in the embodiments of the present application, the drawings that need to be used in the description of the embodiments or the prior art will be briefly described hereinbelow. Obviously, the accompanying drawings in the following description are only some embodiments of the present application. For those skilled in the art, other drawings can be obtained based on these drawings without creative work.

FIG. 1 is a structural schematic diagram of a perovskite solar cell 100 according to an embodiment of the present application;

FIG. 2 is a structural schematic diagram of a perovskite solar cell 100 according to another embodiment of the present application;

FIG. 3 is a flow chart diagram of a method for preparing a perovskite solar cell 100 according to an embodiment of the present application;

FIG. 4 is a schematic diagram of the film deposition process of a perovskite precursor solution comprising the organic molecule in the preparation method of a perovskite solar cell 100 provided in an embodiment of the present application;

FIG. 5 is a flow chart diagram of a method for preparing a perovskite solar cell 100 according to another embodiment of the present application;

FIG. 6 is an electron micrograph of a part of a perovskite solar cell 100 provided in an embodiment of the present application; Part (a) of FIG. 6 shows an interface between the perovskite layer 30 and the electron transport layer 20 without the addition of organic molecules, and Part (b) of FIG. 6 shows an interface between the perovskite layer 30 and the electron transport layer 20 with the addition of organic molecules; and

FIG. 7 is a comparative XRD pattern of a perovskite layer 30 of a perovskite solar cell 100 provided in an embodiment of the present application and a perovskite layer 30 of a comparative example.

The following reference numerals are adopted:

100: perovskite solar cell; 10: first electrode; 20: electron transport layer; 30: perovskite layer; 40: second electrode; and 50: hole transport layer.

### DETAILED DESCRIPTION OF THE EMBODIMENTS

In order to make the technical problems to be solved in the present application, technical solutions, and beneficial effects clearer, the present application will be further described in detail below in conjunction with the embodiments. It should be understood that the specific embodiments described here are only used to explain the present application, but are not intended to limit the present application.

In the present application, the term “and/or” describes the association relationship of associated objects, indicating that there may be three relationships, for example, A and/or B, which may mean the following conditions: A exists alone, A and B exist simultaneously, and B exists alone. Among them, A and B can be singular or plural. The character “/” generally indicates that the contextual objects have an “or” relationship.

In the present application, “at least one” means one or more, and “multiple” means two or more. “At least one of the following” or similar expressions refers to any combination of these items, including any combination of single or plural items.

It should be understood that in various embodiments of the present application, the sequence numbers of the above processes do not mean the order of execution, and some or all steps may be executed in parallel or sequentially, and the execution order of each process shall be determined based on its functions and internal logic and should not constitute any limitation to the implementation process of the embodiments of the present application.

Terms used in the embodiments of the present application are only for the purpose of describing specific embodiments, and are not intended to limit the present application. The singular forms “a”, “said” and “the” used in the embodiments of the present application and the appended claims are also intended to include plural forms unless otherwise clearly indicated in the context.

The masses of the relevant components mentioned of the embodiments of the present application in the specification can not only refer to the specific contents of the component, but also represent the proportional relationship between the masses of the different components. The scaling up or down of the content of the fraction is within the scope disclosed the embodiments of the present application in the specification. Specifically, the mass described the embodiments of the present application in the specification may be g, mg, g, kg and other well-known mass units in the chemical industry.

The terms “first” and “second” are adopted for descriptive purposes only to distinguish different substances and are not to be construed as indicating or implying a relative importance or implicitly indicating the number of technical features indicated. For example, without departing from the scope of the embodiments of the present application, the first XX can also be referred to as the second XX, and similarly, the second XX can also be referred to as the first XX. Thus, features prefixed by “first” and “second” will explicitly or implicitly represent that one or more of the referred technical features are included.

In a typical perovskite solar cell, a surface of the electron transport layer formed by a metal oxide generally has a porous structure, while the perovskite film layer has certain crystal defects, which easily lead to electron-hole recombination. In addition, the interlayer materials between the perovskite film layer and the electron transport layer are difficult to effectively mix, resulting in more pores between the layers. As a result, the free electrons generated by the perovskite are difficult to be effectively transferred to the external circuit by the electron transport layer, which in turn leads to a decline in PSC performance.

In view of the above, the present application fills a perovskite solar cell between the electron transport layer and the perovskite layer with a unique organic molecule. This organic molecule imparts directional perovskite crystal growth, allowing for a tighter interface between the perovskite and electron transport layers. The specific technical solutions are introduced as follows.

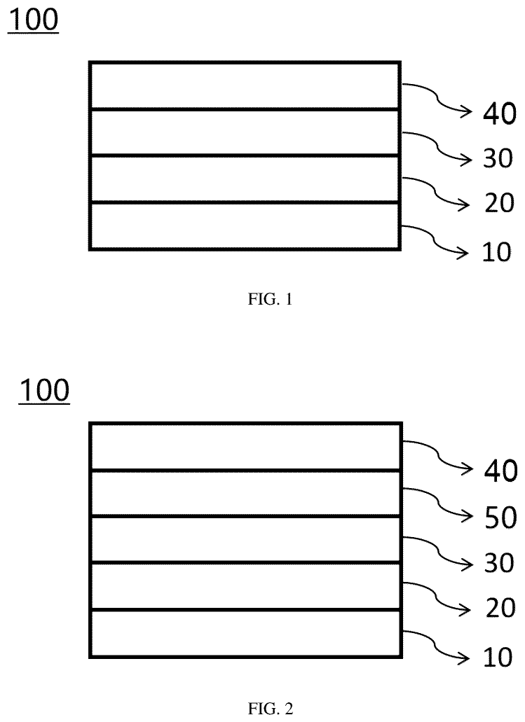

In a first aspect, embodiments of the present application provides a perovskite solar cell 100, as shown in FIG. 1, comprising: a first electrode 10, a second electrode 40, a perovskite layer 30, which is arranged between the first electrode 10 and the second electrode 40; and an electron transport layer 20, which is arranged between the perovskite layer 30 and the first electrode 10. A material of the electron transport layer 20 comprises a metal oxide. An organic molecule represented by Formula I is arranged between the perovskite layer 30 and the electron transport layer 20;

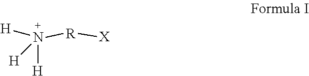

in which, X comprises at least one of a carbonyl group, a carboxyl group, a hydroxyl group, a thiol group, an imine group, a cyano group, and a nitro group, R is —(CH₂)ₙ— or —(CH₂)ₙ— substituted with a hydroxyl group, and n is an integer greater than or equal to 1. X in the organic molecule may bind to the metal oxide on the surface of the electron transport layer 20, while —NH₃⁺ may bind to the perovskite material of the perovskite layer 30.

In the perovskite solar cell 100 provide by embodiments of the present application, the organic molecule represented by Formula I is an organic molecule containing a protonated amino group (—NH₃⁺), that is, an electrically neutral amino group (—NH₂) is protonated to become a positively charged group, and there are various types of Group X, and the aforementioned types of Group X can be combined with the metal oxide. Based on the binding effect of the organic molecule between the electron transport layer 20 and the perovskite layer 30, the porosity between the electron transport layer 20 and the perovskite layer 30 can be improved, making the interlayer bonding closer, which is conducive to improving the electron transport performance and thus improving the energy conversion efficiency of the perovskite solar cell 100.

In some embodiments, X in the organic molecule represented by Formula I is a carboxyl group. The carboxyl group contains two oxygen atoms. The dioxygen chelation coordination of the carboxyl group allows for a tighter bond with the metal oxide, further enhancing the stability of the bond between the electron transport layer 20 and the perovskite layer 30.

In some embodiments, in the organic molecule represented by Formula I, R is —(CH₂)ₙ— or a hydroxyl-substituted —(CH₂)ₙ—, with n ranging from 2 to 5, for example, 2, 3, 4, 5, etc., and is specifically a linear chain. Organic molecules with short carbon chains can further enhance electron transport between the electron transport layer 20 and the perovskite.

In some embodiments, a molar ratio of the organic molecule represented by Formula I to the perovskite material in the perovskite layer 30 is (0.01-0.04):1. For example, the molar ratio of the organic molecule to the perovskite material can be 0.01:1, 0.02:1, 0.04:1, etc. The organic molecule in this ratio can effectively allow the perovskite to fill the porous gaps on the surface of the electron transport layer 20.

In some embodiments, the metal oxide of the electron transport layer 20 comprises at least one of titanium oxide (TiO₂), nickel oxide (NiOₓ), tin oxide (SnO₂), zirconium oxide (ZrO₂), and zinc oxide (ZnO). The electron transport layer 20 can be a single metal oxide layer or two stacked metal oxide layers, such as a dense metal oxide layer and a porous metal oxide layer stacked in sequence. The surface of the electron transport layer 20 to which the organic molecules are bonded refers to the surface of the electron transport layer 20 facing away from the first electrode 10, and generally has a porous structure.

In some embodiments, a perovskite material of the perovskite layer 30 has a chemical formula represented by ABM₃; in which, A is a monovalent cation, which can be an organic cation and/or an inorganic cation, specifically a monovalent organic cation may include at least one of CH₃NH₃⁺ (MA⁺), CH(NH₂)₂⁺ (FA⁺), and a monovalent inorganic cation may include at least one of Rb⁺ and Cs⁺; B is a divalent metal cation, specifically may include at least one of Pb²⁺ and Sn²⁺; M is a monovalent anion, specifically may be a halogen ion, including at least one of Cl⁻, Br⁻ and I⁻.

In some embodiments, as shown in FIG. 2, a hole transport layer 50 may be arranged between the perovskite layer 30 and the second electrode 40 to further enhance the hole transport performance of the perovskite solar cell 100. Specifically, a material of the hole transport layer 50 may include, but not limited to, 2,2′,7,7′-tetrakis[N,N-di(4-methoxyphenyl)amino]-9,9′-spirobifluorene (Spiro-OMeTAD), poly[bis(4-phenyl)(2,4,6-trimethylphenyl)amine](PTAA), poly-3-hexylthiophene (P3HT), triphenylamine with a triptycene core (H101), 3,4-ethylenedioxythiophene-methoxytriphenylamine (EDOT-OMeTPA), N-(4-phenylamino)carbazole-spirobifluorene (CzPAF-SBF), and poly(3, 4-ethylenedioxythiophene):poly(styrenesulfonate) (PEDOT:PSS).

In some embodiments, the first electrode 10 maybe a transparent conductive substrate, including but not limited to the following materials: fluorine-doped tin oxide (FTO), indium-doped tin oxide (ITO), aluminum-doped zinc oxide (AZO), boron-doped zinc oxide (BZO), indium-doped zinc oxide (IZO), etc. The second electrode 40 may be a metal electrode, such as gold, silver, copper, etc., or one or more of conductive oxide electrodes.

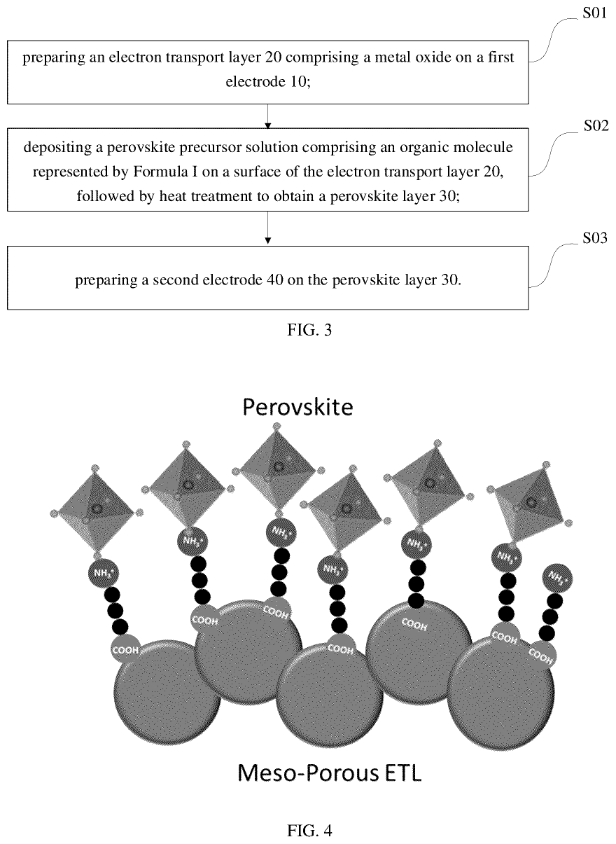

In a second aspect, embodiments of the present application provide a method for fabricating a perovskite solar cell 100. As shown in FIG. 3, the method comprises:
S01: preparing an electron transport layer 20 comprising a metal oxide on a first electrode 10;
S02: depositing a perovskite precursor solution comprising an organic molecule represented by Formula I on a surface of the electron transport layer 20, followed by heat treatment to obtain a perovskite layer 30; and
S03: preparing a second electrode 40 on the perovskite layer 30.

In the method for preparing the perovskite solar cell 100, the perovskite precursor solution comprising an organic molecule represented by Formula I is deposited on a surface of the electron transport layer 20, then heat treatment is performed to obtain a perovskite layer 30. In this process, the organic molecule represented by Formula I acts as a molecular template, and the group X can combine with the metal oxide, while the protonated amino group (—NH₃⁺) can combine with the perovskite material, which is conducive to the nucleation of perovskite crystallization, allowing the perovskite to crystallize and grow along the porous surface of the electron transport layer 20 and fill the porous structure of the electron transport layer 20. The generated perovskite layer 30 can be more tightly combined with the electron transport layer 20, which is beneficial to improving the electron transport performance. The perovskite solar cell 100 finally prepared has good energy conversion efficiency.

Specifically, the perovskite solar cell 100 provided in the first aspect of the present embodiment is prepared using the preparation method provided in the second aspect of the present embodiment.

In step S01, the first electrode 10 may be a transparent conductive substrate, including but not limited to the following materials: fluorine-doped tin oxide, indium-doped tin oxide, aluminum-doped zinc oxide, boron-doped zinc oxide, indium-doped zinc oxide, etc. The metal oxide of the surface-prepared electron transport layer 20 includes at least one of TiO₂, NiOₓ, SnO₂, ZrO₂, and ZnO. It may be a single metal oxide layer or two metal oxide layers, for example, a dense metal oxide layer and a porous metal oxide layer stacked in sequence. This can be prepared by magnetron sputtering or solution spin coating.

In step S02, in the organic molecule represented by formula I in the perovskite precursor solution, X includes at least one of a carbonyl group, a carboxyl group, a hydroxyl group, a thiol group, an imine group, a cyano group, and a nitro group, R is —(CH₂)ₙ— or —(CH₂)ₙ— substituted with a hydroxyl group; and n is an integer greater than or equal to 1, such as n=3-5. The perovskite precursor in the perovskite precursor solution can be a monovalent halide AM and a divalent halide BM₂ corresponding to a chemical formula ABM₃ of the perovskite material.

Taking an organic molecule where X is a carboxyl group and R is —(CH₂)₃— as an example, the chemical formula of the perovskite material is MAPbI₃, as shown in FIG. 4. When the perovskite precursor solution is deposited on the surface of the electron transport layer 20 (ETL) and heated to form a film, the —NH₃⁺ functional group forms a hydrogen bond with the iodine ion in the perovskite, while the carboxyl group at the other end forms a coordination bond with the porous structure of the electron transport layer 20 material, thereby forming a monolayer between the electron transport layer 20 and the perovskite layer 30. This allows the perovskite to be completely and tightly integrated with the porous structure of the electron transport layer 20 surface, effectively utilizing the high electroactive area characteristics of the porous electron transport layer 20, and more effectively transferring more electrons per unit time, thereby reducing hysteresis or electron-hole recombination, thereby improving battery performance.

In some embodiments, the perovskite precursor solution is prepared by the following steps:
dissolving a halide salt corresponding to the organic molecule represented by Formula I and a perovskite precursor in a solvent to obtain the perovskite precursor solution;
or alternatively, dissolving an organic molecule represented by Formula II and a perovskite precursor in the solvent, and adjusting a pH value of a resulting solution to protonate an amino terminus of the organic molecule represented by Formula II to obtain the perovskite precursor solution;

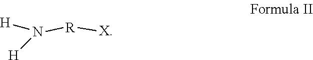

The halide salt corresponding to the organic molecule represented by Formula I, that is, the halide salt formed by the combination of —NH₃⁺ in the molecular structure of Formula I with F⁻, Cl⁻, Br⁻, I⁻ and other ions, can be, for example, 3-propionic acid ammonium iodide, 3-propionic acid ammonium bromide, 4-butyric acid ammonium iodide, 4-butyric acid ammonium bromide, 5-aminopentanoic acid iodide, 5-aminopentanoic acid bromide, 6-aminopentanoic acid iodide, 6-aminopentanoic acid bromide, etc. In the organic molecule represented by Formula II, X and R are the same as those in Formula I, except that the amino group is not protonated, for example, it can be 3-aminopropionic acid, 4-aminobutyric acid, 4-amino-2-hydroxybutyric acid, 6-aminohexanoic acid, and the amino group can be protonated by adjusting the pH value of the solution.

In some embodiments, A molar ratio of the halide salt corresponding to the organic molecule represented by Formula I to the perovskite precursor is (0.01-0.04):1; alternatively, A molar ratio of the organic molecule represented by Formula II to the perovskite precursor is (0.01-0.04):1.

In some embodiments, the solvent includes at least one of dimethyl sulfoxide (DMSO) and N,N-dimethylformamide (DMF). For example, a mixed solvent of DMF and DMSO in a weight ratio of (3-5):1 can be used to better dissolve the organic molecule and the perovskite precursor.

In some embodiments, the temperature of the heat treatment is 100° C. to 150° C. This temperature condition allows the perovskite precursor solution to be annealed well to form a film.

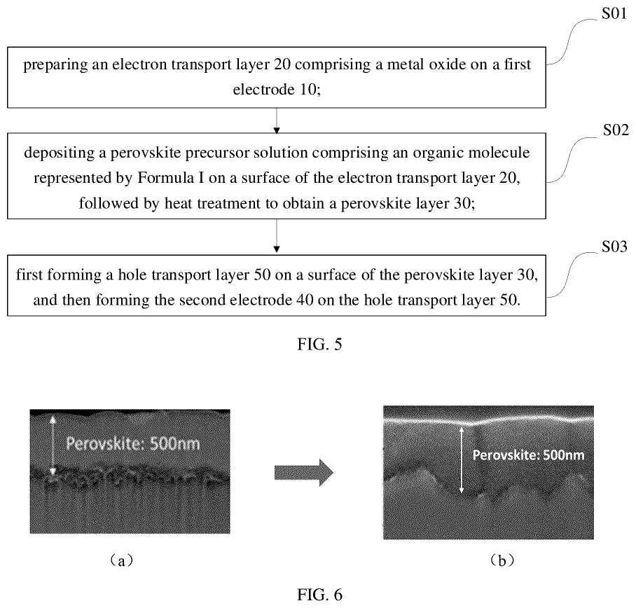

As shown in FIG. 5, in step S03, the step of forming a second electrode 40 on the perovskite layer 30 may specifically include: first forming a hole transport layer 50 on a surface of the perovskite layer 30, and then forming the second electrode 40 on the hole transport layer 50. The hole transport layer 50 material may include 2,2′,7,7′-tetrakis[N,N-di(4-methoxyphenyl)amino]-9,9′-spirobifluorene, poly[bis(4-phenyl)(2,4,6-trimethylphenyl)amine], poly-3-hexylthiophene, triphenylamine with a triptycene core, 3,4-ethylenedioxythiophene-methoxytriphenylamine, N-(4-phenylamino)carbazole-spirobifluorene, poly(3,4-ethylenedioxythiophene):poly(styrenesulfonate), etc. The second electrode 40 may be a metal electrode or a conductive oxide electrode.

The following describes the details in conjunction with specific embodiments.

### Example 1

A perovskite solar cell 100 and a preparation method are provided in this example. The perovskite solar cell 100 comprises: a first electrode 10 (material: FTO substrate), an electron transport layer 20 (with a material comprising stacked dense TiO₂ layer and meso-TiO₂ layer), a perovskite layer 30 (material: MAPbI₃), a hole transport layer 50 (material: Spiro-OMeTAD), and a second electrode 40 (material: gold). An organic molecule represented by Formula I is bonded between the perovskite layer 30 and the electron transport layer 20, where R is —(CH₂)₂— and X is a carboxyl group.

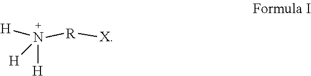

The perovskite solar cell 100 was prepared by the following steps:

In step 1, a conductive FTO substrate was cleaned. Thereafter, TiO₂ was sputter-coated onto the FTO substrate, and a meso-TiO₂ nanoparticle suspension was spin-coated onto a resulting FTO substrate at a rotational speed of 4000 rpm, followed by annealing at a temperature of 450° C. to form an electron transport layer 20 having a thickness of approximately 200 nm.

In step 2, a perovskite precursor solution was prepared as follows: PbI₂ and MAI were dissolved in a mixed solvent (DMF and DMSO in a weight ratio of 4:1), in which, a molar ratio of PbI₂ to MAI was 3:1, and a concentration of MAI is 0.25 M (mol/L). Then, 3-propionic acid ammonium iodide was added at a molar ratio of 3-propionic acid ammonium iodide to PbI₂ being 0.01:1. Once uniformly dispersed, the perovskite precursor solution was obtained. The perovskite precursor solution was spin-coated on the electron transport layer 20 at a rotational speed of 2000 rpm and annealed at a temperature of 130° C. to obtain a perovskite layer 30 having a thickness of approximately 500 nm.

In step 3, a chlorobenzene solution of Spiro-OMeTAD was spin coated onto the perovskite layer 30 at a rotational speed of 4000 rpm and anneal at a temperature of 100° C. to form a hole transport layer 50 having a thickness of approximately 200 nm.

In step 4: the hole transport layer 50 was sputter-coated with gold to yield a layer having a thickness of approximately 80 nm, thereby forming the second electrode 40.

### Comparative Example 1

A preparation method for a perovskite solar cell 100 provided in this comparative example differs from the preparation steps of Example 1 in that 3-aminopropionic acid was replaced with 3-ammonium iodide when preparing the perovskite precursor solution, and the solution remained neutral, so that the amino groups of the organic molecules were not protonated. Other steps were the same as those of Example 1.

### Comparative Example 2

A preparation method for a perovskite solar cell 100 provided in this comparative example differs from the preparation steps of Example 1 in that 3-ammonium iodide was not added when preparing the perovskite precursor solution. Other steps were the same as those of Example 1.

### Performance Testing

### (1) Microscopic Electron Microscope Image

As shown in FIG. 6, Part (a) of FIG. 6 shows an interface between the perovskite layer 30 and the electron transport layer 20 without the addition of organic molecules, and Part (b) of FIG. 6 shows an interface between the perovskite layer 30 and the electron transport layer 20 with the addition of organic molecules.

This demonstrates that after adding the organic molecular template containing protonated amino groups to the perovskite precursor solution in Example 1, it can be clearly observed that the perovskite layer 30 and the porous electron transport layer 20 are tightly bonded, with virtually no unfilled porous structures observed.

### (2) XRD Pattern

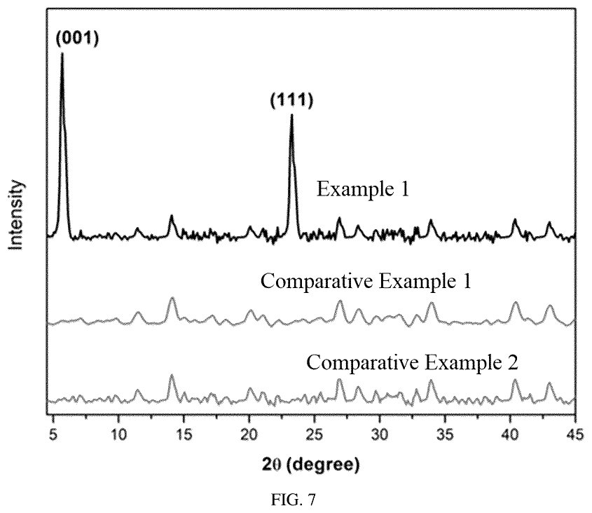

As shown in FIG. 7, the protonated amino-containing molecular template in Example 1 allows the perovskite crystal growth to be directional, resulting in a unique XRD pattern with strong (001) and (111) planes at 2θ≈5.8° and 23.2°. Comparative Examples 1 and 2 do not exhibit this effect. Therefore, the protonated amino-containing molecular template allows the perovskite to crystallize along the porous electron transport layer 20 and fill the porous structure of the porous electron transport layer 20.

### (3) Perovskite Solar Cell 100 Performance Test

The perovskite solar cell 100s prepared in the above examples and comparative examples each were respectively connected to a solar simulator and a test fixture of a battery performance tester, and an I-V curve scan was performed. Then, the energy conversion efficiency PCE_{avg}, short-circuit current (Jsc), open-circuit voltage (Voc) and fill factor (FF) were calculated. The results are shown in Table 1.

TABLE 1

| Examples | PCE_{avg}/% | Jsc/mAcm⁻² | Voc/V | FF |
|---|---|---|---|---|
| Comparative | 16.48 | 21.06 | 0.76 | 0.67 |
| example 2 | | | | |
| Comparative | 16.37 | 20.99 | 0.72 | 0.65 |
| example 1 | | | | |
| Example 1 | 18.98 | 24.33 | 1.01 | 0.78 |

As can be seen from the above, Example 1 reduces the defect density of the perovskite material due to the addition of a protonated molecular template, thereby improving various performances of the cell. Compared with Comparative Example 2, Comparative Example 1 adds a non-protonated molecular template. From the experimental results, it can be seen that the battery efficiency performance is not improved, but it is expected that the stability can be improved to a certain extent. The perovskite solar cell 100 prepared in Example 1 of the present application can more effectively transfer more electrons per unit time, improving the battery conversion efficiency performance.

The above description is only a preferred embodiment of the present application and is not intended to limit the present application. Any modifications, equivalent replacements and improvements made within the spirit and principles of the present application should be included in the scope of protection of the present application.

What is claimed is:

1. A perovskite solar cell, comprising:
a first electrode,
a second electrode,
a perovskite layer, which is arranged between the first electrode and the second electrode; and
an electron transport layer, which is arranged between the perovskite layer and the first electrode;
wherein
a material of the electron transport layer comprises a metal oxide, and
an organic molecule represented by Formula I is arranged between the perovskite layer and the electron transport layer; 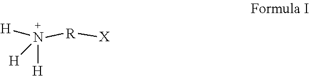
wherein X comprises at least one of a carbonyl group, a carboxyl group, a hydroxyl group, a thiol group, an imine group, a cyano group, and a nitro group, R is —(CH₂)ₙ— or —(CH₂)ₙ— substituted with a hydroxyl group, and n is an integer greater than or equal to 1; and X in the organic molecule is adjacent to the electron transport layer, and —NH₃⁺ in the organic molecule is adjacent to the perovskite layer.

2. The perovskite solar cell according to claim 1, wherein X is a carboxyl group; and/or n=2-5.

3. The perovskite solar cell according to claim 2, wherein a molar ratio of the organic molecule to the perovskite material in the perovskite layer is (0.01-0.04):1.

4. The perovskite solar cell according to claim 1, wherein
the metal oxide comprises at least one of TiO₂, NiOₓ, SnO₂, ZrO₂, and ZnO; and/or
a hole transport layer is arranged between the perovskite layer and the second electrode.

5. The perovskite solar cell according to claim 2, wherein
the metal oxide comprises at least one of TiO₂, NiOₓ, SnO₂, ZrO₂, and ZnO; and/or
a hole transport layer is arranged between the perovskite layer and the second electrode.

6. The perovskite solar cell according to claim 3, wherein
the metal oxide comprises at least one of TiO₂, NiOₓ, SnO₂, ZrO₂, and ZnO; and/or
a hole transport layer is arranged between the perovskite layer and the second electrode.

7. A method for preparing the perovskite solar cell according to claim 1, comprising:
preparing the electron transport layer comprising the metal oxide on the first electrode;
depositing a perovskite precursor solution comprising the organic molecule represented by Formula I on a surface of the electron transport layer, followed by heat treatment to obtain the perovskite layer; and
preparing the second electrode on the perovskite layer; 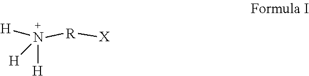
wherein X comprises at least one of a carbonyl group, a carboxyl group, a hydroxyl group, a thiol group, an imine group, a cyano group, and a nitro group, R is —(CH₂)ₙ— or —(CH₂)ₙ— substituted with a hydroxyl group, and n is an integer greater than or equal to 1.

8. The method according to claim 7, wherein the perovskite precursor solution is prepared by the following steps:
dissolving a halide salt corresponding to the organic molecule represented by Formula I and a perovskite precursor in a solvent to obtain the perovskite precursor solution.

9. The method according to claim 7, wherein the perovskite precursor solution is prepared by the following steps:
dissolving an organic molecule represented by Formula II and a perovskite precursor in a solvent, and adjusting a pH value of a resulting solution to protonate an amino terminus of the organic molecule represented by Formula II to obtain the perovskite precursor solution;

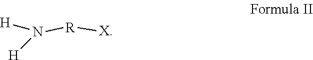

10. The method according to claim 8, wherein
a molar ratio of the halide salt corresponding to the organic molecule represented by Formula I to the perovskite precursor is (0.01-0.04):1.

11. The method according to claim 9, wherein
a molar ratio of the organic molecule represented by Formula II to the perovskite precursor is (0.01-0.04):1.

12. The method according to claim 8, wherein the solvent comprises at least one of dimethyl sulfoxide and N,N-dimethylformamide.

13. The method according to claim 9, wherein the solvent comprises at least one of dimethyl sulfoxide and N,N-dimethylformamide.

14. The method according to claim 7, wherein a temperature of the heat treatment is 100° C. to 150° C.

15. The method according to claim 8, wherein a temperature of the heat treatment is 100° C. to 150° C.

16. The method according to claim 9, wherein a temperature of the heat treatment is 100° C. to 150° C.

17. The method according to claim 7, wherein
the step of preparing the second electrode on the perovskite layer comprises: preparing a hole transport layer on a surface of the perovskite layer, and preparing the second electrode on the hole transport layer.

18. The method according to claim 7, wherein X is a carboxyl group; n=2-5.

19. The method according to claim 7, wherein a molar ratio of the organic molecule to the perovskite material in the perovskite layer is (0.01-0.04):1.

20. The method according to claim 7, wherein the metal oxide comprises at least one of TiO₂, NiOₓ, SnO₂, ZrO₂, and ZnO.
